(19) United States
(12) Patent Application Publication
(10) Pub. No.: US 2025/0069966 A1
(43) Pub. Date: Feb. 27, 2025

(54) C2W STRUCTURE AND METHOD FOR MAKING SAME

(71) Applicant: WUHAN XINXIN SEMICONDUCTOR MANUFACTURING CO., LTD., Wuhan (CN)

(72) Inventors: Sheng HU, Wuhan (CN); Shengjin SONG, Wuhan (CN); Guoliang YE, Wuhan (CN)

(21) Appl. No.: 18/543,046

(22) Filed: Dec. 18, 2023

(30) Foreign Application Priority Data
Aug. 24, 2023 (CN) 202311079349.4

(51) Int. Cl. H01L 23/13; H01L 23/31; H01L 25/00; H01L 25/065

(52) U.S. Cl. CPC H01L 23/13; H01L 23/3121; H01L 25/0655; H01L 25/50

(57) ABSTRACT

A chip-to-wafer (C2W) structure and a method for making the C2W structure are disclosed. The C2W structure includes a first semiconductor substrate, a plurality of chips located above the first semiconductor substrate, a dielectric layer covering the first semiconductor substrate and a second semiconductor substrate covering the plurality of chips and the dielectric layer. The C2W structure has greatly improved heat dissipation performance.

### CROSS-REFERENCE TO RELATED APPLICATION

This application claims the priority of Chinese patent application number 2023110793494, filed on Aug. 24, 2023, and entitled “C2W STRUCTURE AND METHOD FOR MAKING SAME”, the entire contents of which are incorporated herein by reference.

### TECHNICAL FIELD

The present invention relates to the field of semiconductor technology and, in particular, to a chip-to-wafer (C2W) structure and a method for making the structure.

### BACKGROUND

As the microelectronics industry steps into the post-Moore's law era, chip structures are evolving toward three-dimensional (3D) stacking, which enables higher integration, greater miniaturization and more excellent performance. Compared with wafer-to-wafer (W2W) stacking, chip-to-wafer (C2W) heterogeneous integration is advantageous in allowing interconnection between dies of different technology nodes and different sizes with higher flexibility. Moreover, C2W integration allows known good dies (KGDs) to be chosen to be bonded to a wafer. This can result in a significantly increased yield of stacking up multiple dies. C2W integration has become an important area of development for 3D-IC technology. However, existing C2W structures suffer from the problem of poor heat dissipation.

### SUMMARY OF THE INVENTION

It is an object of the present invention to provide a C2W structure and a method for making the structure, which overcome the problem of poor heat dissipation associated with existing C2W structures.

To this end, the present invention provides a C2W structure, comprising:
a first semiconductor substrate;
a plurality of chips located above the first semiconductor substrate;
a dielectric layer covering the first semiconductor substrate; and
a second semiconductor substrate covering the plurality of chips and the dielectric layer.

Optionally, in the C2W structure, at least one first trench may be formed in the second semiconductor substrate, wherein the first trench extends from a first surface of the second semiconductor substrate that is in contact with the plurality of chips into the second semiconductor substrate.

Optionally, in the C2W structure, a plurality of first trenches may be formed in the second semiconductor substrate, wherein the plurality of first trenches are arranged in a mesh structure in a first direction and a second direction.

Optionally, in the C2W structure, a plurality of first trenches may be formed in the second semiconductor substrate, wherein the plurality of first trenches form a plurality of trench regions, and wherein each trench region is aligned with a corresponding chip.

Optionally, in the C2W structure, a metal layer, or a thermally conductive fluid may be provided in the at least one first trench.

Optionally, in the C2W structure, the at least one first trench may have a depth-to-width ratio lying between 1:1 and 2:1.

Optionally, in the C2W structure, a second trench may be formed in the dielectric layer, wherein the second trench extends from a second surface of the dielectric layer that is in contact with the second semiconductor substrate into the dielectric layer.

Optionally, in the C2W structure, a single second trench may surround at least one chip.

Optionally, in the C2W structure, a plurality of second trenches may be formed in the dielectric layer, wherein each second trench surrounds a corresponding chip.

The present invention also provides a method for making a C2W structure, which comprises:
providing a first semiconductor substrate;
bonding a plurality of chips to the first semiconductor substrate;
covering the first semiconductor substrate with a dielectric layer; and
covering the plurality of chips and the dielectric layer with a second semiconductor substrate.

Optionally, in the method, covering the plurality of chips and the dielectric layer with the second semiconductor substrate may comprise:
providing the second semiconductor substrate;
forming a first trench in the second semiconductor substrate, wherein the first trench extends from a first surface of the second semiconductor substrate into the second semiconductor substrate; and
covering the plurality of chips and the dielectric layer with the second semiconductor substrate, wherein the first surface comes into contact with the plurality of chips and the dielectric layer.

Optionally, in the method, covering the first semiconductor substrate with the dielectric layer may comprise:
forming the dielectric layer, wherein the dielectric layer covers surfaces of the chips and the first semiconductor substrate uncovered by the chips;
removing the dielectric layer above the surfaces of the chips; and
forming at least one second trench in the dielectric layer, wherein the at least second trench extends from a second surface of the dielectric layer into the dielectric layer.

Optionally, in the method, a metal layer or a thermally conductive fluid may be provided in the first trench.

Optionally, in the method, the first trench may have a depth-to-width ratio lying between 1:1 and 2:1.

Optionally, in the method, a single second trench may surround at least one chip.

In the C2W structure and method provided in the present invention, the second semiconductor substrate covering the plurality of chips and the dielectric layer provides heat dissipation properties several times better than the dielectric layer, allowing the resulting chip-to-wafer (C2W) heterogeneously integrated structure to have greatly improved heat dissipation performance.

### BRIEF DESCRIPTION OF THE DRAWINGS

FIG. 1 is a schematic flowchart of a method for making a C2W structure according to an embodiment of the present invention.

FIG. 2 is a schematic cross-sectional view of an intermediate device structure resulting from forming a dielectric layer on surfaces of chips and above a first semiconductor substrate uncovered by the chips in a method for making a C2W structure according to an embodiment of the present invention.

FIG. 3 is a schematic cross-sectional view of an intermediate device structure resulting from removing a dielectric layer above surfaces of chips in a method for making a C2W structure according to an embodiment of the present invention.

FIG. 4 is a schematic cross-sectional view of an intermediate device structure resulting from forming second trenches in a dielectric layer in a method for making a C2W structure according to an embodiment of the present invention.

FIG. 5 is a schematic cross-sectional view of an intermediate device structure resulting from providing a second semiconductor substrate in a method for making a C2W structure according to an embodiment of the present invention.

FIG. 6 is a schematic cross-sectional view of an intermediate device structure resulting from forming first trenches in a second semiconductor substrate in a method for making a C2W structure according to an embodiment of the present invention.

FIG. 7 is a schematic cross-sectional view of an intermediate device structure resulting from covering a plurality of chips and a dielectric layer with a second semiconductor substrate in a method for making a C2W structure according to an embodiment of the present invention.

FIG. 8 is a schematic top view of an intermediate device structure resulting from forming second trenches in a dielectric layer in a method for making a C2W structure according to an embodiment of the present invention.

FIG. 9 is a schematic top view of an intermediate device structure resulting from forming first trenches in a second semiconductor substrate in a method for making a C2W structure according to an embodiment of the present invention.

In these figures,
100, a first semiconductor substrate; 110, a dielectric material layer; 120, a rewiring layer; 200, a chip; 300, a dielectric layer; 310, a second trench; 400, a second semiconductor substrate; 410, a first trench; and 420, a trench region.

### DETAILED DESCRIPTION

C2W structures and methods provided therein will be described in greater detail below with reference to specific embodiments and to the accompanying drawings. Advantages and features of the present invention will become more apparent from the following description and from the appended claims. Note that the drawings are provided in a very simplified form not necessarily drawn to exact scale for the only purpose of facilitating easy and clear description of the disclosed embodiments.

The terminology used herein is used for the purpose of describing particular embodiments only, and is not intended to limit the scope of the present invention. Unless defined otherwise herein, all technical and scientific terms used herein have the same meaning as commonly understood by one of ordinary skill in the art to which the invention belongs. As used herein and in the appended claims, the terms “first,” “second,” and the like do not denote any order, quantity, or importance, but rather are used to distinguish one element from another. Likewise, the terms “a” and “an” do not denote a limitation of quantity, but rather denote the presence of at least one of the referenced items. The terms “plurality” or “several” means two or more than two. Unless otherwise specified, the terms “upper/upper layer”, “lower/lower layer” and/or the like used herein are merely for ease of description, and should not be construed as being limited to a particular position or a particular spatial orientation. The use of “including” or “comprising” or the like herein is meant to encompass the items listed thereafter and equivalents thereof but do not preclude the presence of other items. The terms “connected”, “coupled” or the like are not restricted to physical or mechanical connections or couplings, and can include electrical connections or couplings, whether direct or indirect. As used herein and in the appended claims, the singular forms “a”, “an”, and “the” are intended to include the plural forms as well, unless the context clearly indicates otherwise. It will be also understood that, as used herein, the term “and/or” includes any and all combinations of one or more of the associated listed items.

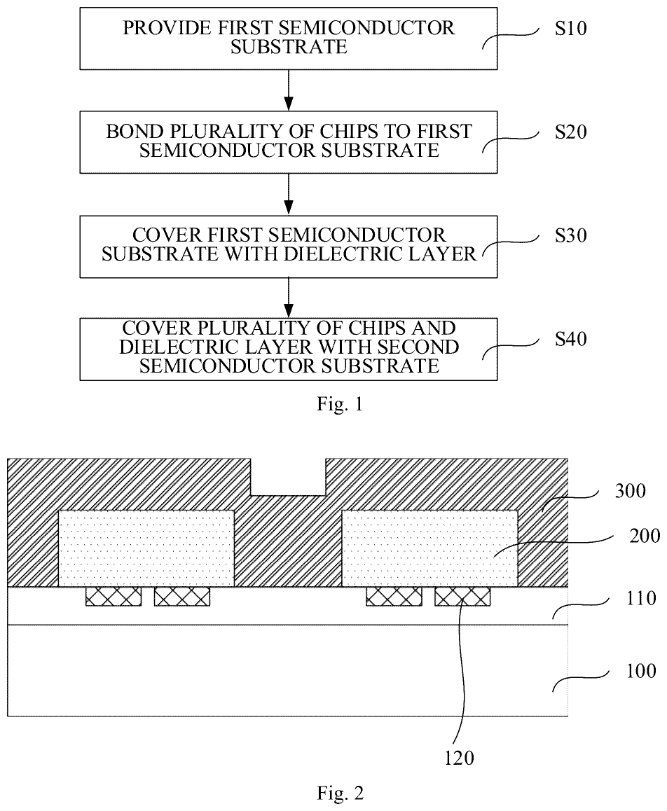

Reference is now made to FIG. 1, a schematic flowchart of a method for making a C2W structure according to an embodiment of the present invention. As shown in FIG. 1, according to embodiments of this application, the method specifically includes the steps of:
S10: providing a first semiconductor substrate;
S20: bonding a plurality of chips to the first semiconductor substrate;
S30: covering the first semiconductor substrate with a dielectric layer; and
S40: covering the plurality of chips and the dielectric layer with a second semiconductor substrate.

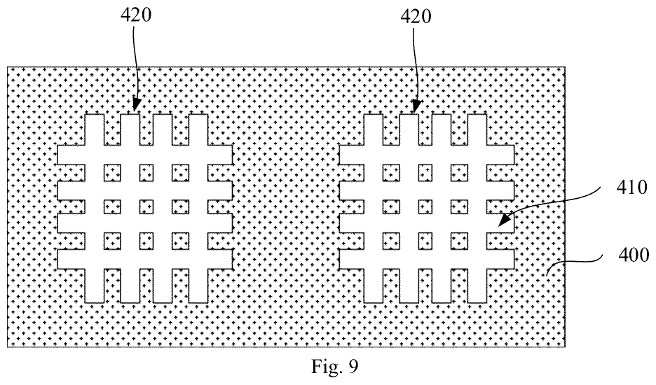

Additional reference is made to FIGS. 2 to 9. FIGS. 2 to 7 are schematic cross-sectional views of intermediate structures formed in a method for making a C2W structure according to an embodiment of the present invention. FIGS. 8 to 9 are schematic top views of devices fabricated using methods for making a C2W structure according to embodiments of the present invention.

As shown in FIG. 2, first of all, a first semiconductor substrate 100 is provided. Examples of the substrate may include, but are not limited to, silicon, silicon germanium, silicon carbide, gallium nitride and gallium arsenide substrates. In the embodiments disclosed herein, the first semiconductor substrate 100 is a silicon substrate.

On the first semiconductor substrate 100, a dielectric material layer 110 and a rewiring layer 120 located in the dielectric material layer 110 may be formed. Suitable materials for the dielectric material layer 110 may include, but are not limited to, silicon oxide or silicon nitride. Suitable materials for the rewiring layer 120 may include, but are not limited to, copper.

A plurality of chips 200 are then bonded to the first semiconductor substrate 100. In the embodiments disclosed herein, the bonding of the plurality of chips 200 to the first semiconductor substrate 100 may be accomplished using a known bonding technique such as hybrid bonding, fusion bonding or micro-bump bonding. The plurality of chips 200 may be of the same function. Alternatively, some of the chips 200 may be of the same function, while the others may be of the same or different functions. Alternatively, each of them may be of a different function. Additionally, the plurality of chips 200 may be of the same size. Alternatively, some of the chips 200 may be of the same size, while the others may be of the same or different sizes. Alternatively, each of them may be of a different size. In FIG. 2, two of the chips 200 are shown for illustration. Each chip 200 may include a semiconductor substrate and a dielectric material layer formed on the semiconductor substrate. Suitable materials for the chips 200 may include, but are not limited to, silicon, silicon germanium, silicon carbide, gallium nitride and gallium arsenide.

With continued reference to FIG. 2, a dielectric layer 300 is then formed, which covers the first semiconductor substrate 100 uncovered by the chips 200 and surfaces of the chips 200. That is, dielectric layer 300 fills gaps around the chips 200 and covers the surfaces of the chips 200. Suitable materials for the dielectric layer 300 may include, but are not limited to, silicon oxide and silicon nitride. The dielectric layer 300 has excellent isolation properties, is cheap and easily available, and can be filled between the chips 200 and cover a surface of the first semiconductor substrate 100 uncovered by the chips 200 in a satisfactory manner. However, the dielectric layer 300 has poor heat dissipation properties, making the resulting C2W structure inferior in terms of heat dissipation performance.

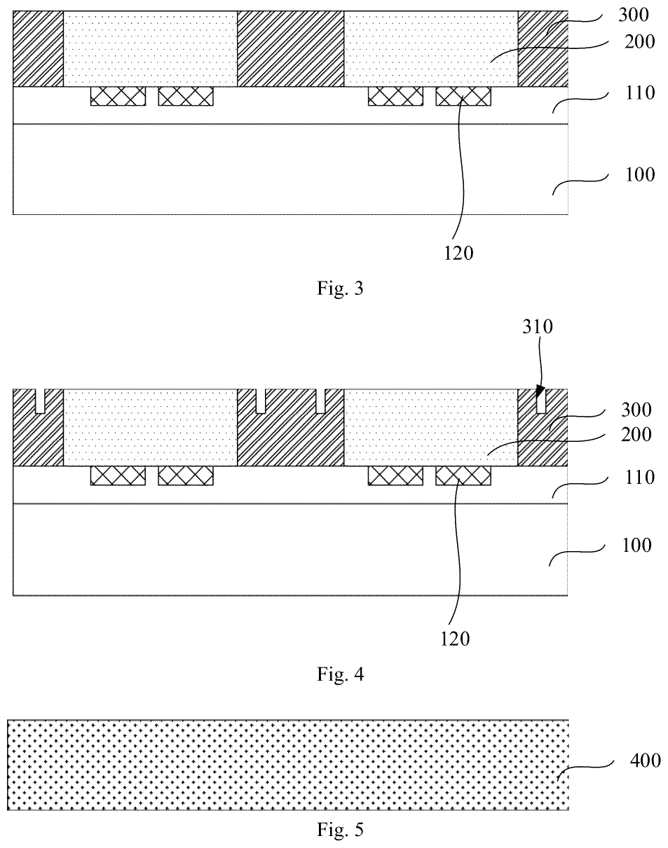

Referring to FIG. 3, in the embodiments disclosed herein, the dielectric layer 300 above the surface of the chips 200 is removed, optionally using a grinding process, to expose the chips 200 and to form a flat device surface. Preferably, multiple grinding processes may be employed, including, for example, an initial coarse grinding process, in which a grinding wheel is used to quickly remove the majority portion of the dielectric layer 300 above the surfaces of the chips 200, and a subsequent fine chemical mechanical polishing (CMP) process for finely grinding away the remaining portion of the dielectric layer 300 above the surfaces of the chips 200, resulting in a flat device surface with high quality.

As shown in FIG. 4, in the embodiments disclosed herein, second trenches 310 are formed in the dielectric layer 300, which extend from a second surface of the dielectric layer 300 into the dielectric layer 300. Here, the second surface refers to the surface of the dielectric layer 300 facing away from the first semiconductor substrate 100. Either a single or multiple second trenches 310 may be formed.

Specifically, an etching process may be employed to form the second trenches 310 in the dielectric layer 300. For example, a patterned photoresist layer (not shown) may be formed on the dielectric layer 300. Subsequently, with the patterned photoresist layer serving as a mask, the dielectric layer 300 may be etched to form the second trenches 310, followed by lift-off of the patterned photoresist layer. Preferably, after the second trenches 310 are formed in the dielectric layer 300, another CMP process may be performed on the device surface to additionally enhance its quality. This can facilitate the performance of the subsequent processes and impart higher quality and higher reliability to the resulting C2W structure.

Reference is now made to FIG. 8, a schematic top view of an intermediate device structure resulting from forming second trenches in a dielectric layer in a method for making a C2W structure according to an embodiment of the present invention. The second trenches 310 may have any cross-sectional shape known in the art taken either parallel or perpendicular to the second surface, such as linear or folded linear. In the embodiments disclosed herein, two of the second trenches 310 are schematically illustrated, which are shaped like square annuli and encircle the two chips 200 respectively. That is, one of the second trenches 310 surrounds one of the chips 200, and the other second trench 310 encircles the other chip 200.

In other embodiments of the present application, the second trenches 310 may be otherwise shaped to facilitate heat dissipation. For example, the second trenches 310 may generally comprise an 8-like shape, and the two chips 200 may be surrounded by two rings of the 8-like shape of the second trenches 310. In this case, a single second trench may encircle two chips 200. Likewise, in case of more chips 200, more such rings may be formed, in order to enhance heat dissipation of these chips 200.

In other embodiments of the present application, a plurality of second trenches 310 may be formed and arranged in a different manner. For example, the second trenches 310 may be linear in shape, and a plurality of second trenches 310 may be arranged side by side in a first direction and/or a second direction to form a multiple second trench groups, and there is one second trench group on one or more sides of each chip 200.

Preferably, the second trenches 310 have a depth-to-width ratio lying between 1:1 and 2:1, such as 1:1, 1.2:1, 1.5:1, 1.8:1 or 2:1. This can not only impart better heat dissipation performance to the resulting C2W structure, but can also facilitate the formation of the second trenches. According to the present application, the depth-to-width ratio of the second trenches 310 may lie between different values.

Further, a metal layer may be formed in the second trenches 310 (the metal layer is accordingly referred to as the “second metal layer” hereinafter). Metals are known to have excellent heat dissipation properties, and therefore forming the second metal layer in second trenches 310 can impart even better heat dissipation performance to the resulting C2W structure. In other embodiments of the present application, a thermally conductive fluid may be subsequently introduced into the second trenches 310, such as a fluorinated fluid or nano-coating material. Specifically, the C2W structure may be so formed that there is an inlet left therein for the thermally conductive fluid in communication with the second trenches 310. The thermally conductive fluid may be introduced into the second trenches 310 via the inlet.

Subsequently, referring to FIG. 5, a second semiconductor substrate 400 is provided. Examples of the substrate may include, but are not limited to, silicon, silicon germanium, silicon carbide, gallium nitride and gallium arsenide substrates. In the embodiments disclosed herein, the second semiconductor substrate 400 is a silicon substrate.

In one embodiment of the present application, the plurality of chips 200 and the dielectric layer 300 may be then covered with the second semiconductor substrate 400. Preferably, the second semiconductor substrate 400 directly contacts the semiconductor substrates of the chips 200. The second semiconductor substrate 400 has good heat dissipation properties, several times better than the dielectric layer. Therefore, it allows the resulting C2W structure to have greatly improved heat dissipation performance. Preferably, the second semiconductor substrate 400 is bonded to the plurality of chips 200 and the dielectric layer 300.

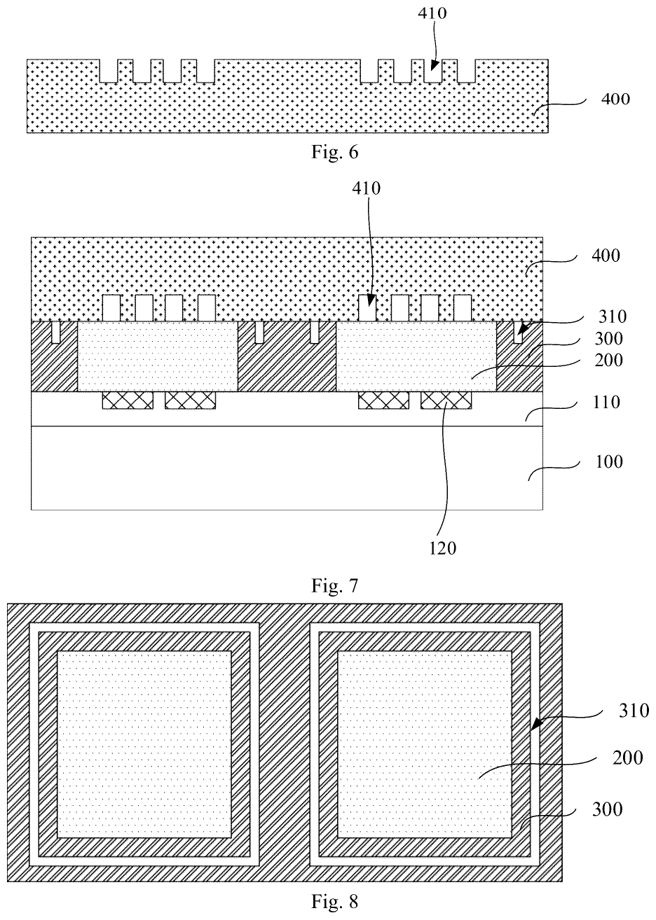

Referring to FIG. 6, in another embodiment of the present application, first trenches 410 are then formed in the second semiconductor substrate 400, which extend from a first surface of the second semiconductor substrate 400 into the second semiconductor substrate 400. Here, the first surface refers to the surface of the second semiconductor substrate 400 subsequently engaged with the plurality of chips 200 and the dielectric layer 300. The first trenches 410 may have any cross-sectional shape known in the art taken either parallel or perpendicular to the first surface, such as linear or folded linear. Further, either a single or multiple first trenches 410 may be formed.

Specifically, an etching process may be employed to form the first trenches 410 in the second semiconductor substrate 400. For example, a patterned photoresist layer (not shown) may be formed on the second semiconductor substrate 400. Subsequently, with the patterned photoresist layer serving as a mask, the second semiconductor substrate 400 may be etched to form the first trenches 410, followed by lift-off of the patterned photoresist layer. Preferably, after the first trenches 410 are formed in the second semiconductor substrate 400, a CMP process may be performed on the first surface of the second semiconductor substrate 400 to enhance its quality. This can facilitate the engagement of the second semiconductor substrate 400 with the plurality of chips 200 and the dielectric layer 300, thereby imparting higher quality and higher reliability to the resulting C2W structure.

Reference is now made to FIG. 9, a schematic top view of an intermediate device structure resulting from forming first trenches in a second semiconductor substrate in a method for making a C2W structure according to an embodiment of the present invention. In the embodiments disclosed herein, the first trenches 410 may be linear in shape and extend side by side in the first direction and/or the second direction. FIG. 9 schematically illustrates sixteen first trenches 410 arranged in a mesh structure. Specifically, eight of the first trenches 410 extend in the first direction parallel to the first surface and the other eight first trenches 410 extend in the second direction parallel to the first surface so that they form the mesh arrangement. The first direction may cross the second direction at any angle. Preferably, first and second directions may be perpendicular to each other.

Further, the first trenches 410 extending in the first and second directions may cross each other to form arrays, referred to hereinafter as trench regions 420, each aligned with a corresponding one of the chips 200. In FIG. 9, the sixteen first trenches 410 form two trench regions 420 aligned with the two chips 200. In the embodiments disclosed herein, four of the first trenches 410 extending in the first direction and four of the first trenches 410 extending in the second direction form a first mesh structure, and the other four of the first trenches 410 extending in the first direction and the other four of the first trenches 410 extending in the second direction form a second mesh structure. These two mesh structures correspond to the two trench regions 420 and are aligned with the two chips 200, so as to additionally enhance heat dissipation of the chips 200.

The first trenches 410 may be otherwise shaped and arranged, without departing from the scope of the present application.

In the embodiments disclosed herein, the first trenches 410 and/or the second trenches 310 allow the resulting C2W structure to have a larger area for heat dissipation. This greatly improves the heat dissipation performance of the C2W structure.

Preferably, the first trenches 410 have a depth-to-width ratio lying between 1:1 and 2:1, such as 1:1, 1.2:1, 1.5:1, 1.8:1 or 2:1. This can not only impart better heat dissipation performance to the resulting C2W structure, but can also facilitate the formation of the first trenches 410. According to the present application, the depth-to-width ratio of the first trenches 410 may lie between different values.

Further, a metal layer may be formed in the first trenches 410 (the metal layer is accordingly referred to as the “first metal layer” hereinafter). Metals are known to have excellent heat dissipation properties, and therefore forming the first metal layer in first trenches 410 can impart even better heat dissipation performance to the resulting C2W structure. In other embodiments of the present application, a thermally conductive fluid may be subsequently introduced into the first trenches 410, such as a fluorinated fluid or nano-coating material. Specifically, the C2W structure may be so formed that there is an inlet left therein for the thermally conductive fluid in communication with the first trenches 410. The thermally conductive fluid may be introduced into the first trenches 410 via the inlet.

The provision of the second semiconductor substrate 400 and the formation of the first trenches 410 therein may occur in parallel with the formation of the dielectric layer 300 and the second trenches 310 therein. Alternatively, the provision of the second semiconductor substrate 400 and the formation of the first trenches 410 therein may precede the formation of the dielectric layer 300 and the second trenches 310 therein. Still alternatively, the formation of the dielectric layer 300 and the second trenches 310 therein may precede the provision of the second semiconductor substrate 400 and the formation of the first trenches 410 therein. The present application is not limited in this regard.

After that, referring to FIG. 7, the plurality of chips 200 and the dielectric layer 300 are covered with the second semiconductor substrate 400, and the first surface contacts the plurality of chips 200 and the dielectric layer 300. The first surface of the second semiconductor substrate 400 may be brought into contact with the second surface of the dielectric layer 300. The second semiconductor substrate 400 has good heat dissipation properties, several times better than the dielectric layer. Therefore, it allows the resulting C2W structure to have greatly improved heat dissipation performance. In particular, the first trenches 410 formed in the second semiconductor substrate 400 and the second trenches 310 formed in the dielectric layer 300 allow the resulting C2W structure to have a larger area for heat dissipation. This greatly improves the heat dissipation performance of the C2W structure. Preferably, the second semiconductor substrate 400 is bonded to the plurality of chips 200 and the dielectric layer 300.

Correspondingly, embodiments of the present application also provide a C2W structure. With continued reference to FIG. 7, the C2W structure includes a first semiconductor substrate 100, a plurality of chips 200 located above the first semiconductor substrate 100, a dielectric layer 300 covering the first semiconductor substrate 100, and a second semiconductor substrate 400 covering the plurality of chips 200 and the dielectric layer 300.

In the embodiments disclosed herein, first trenches 410 are formed in the second semiconductor substrate 400, which extend from a first surface of the second semiconductor substrate 400 in contact with the plurality of chips 200 into the second semiconductor substrate 400. Second trenches 310 are formed in the dielectric layer 300, which extend from a second surface of the dielectric layer 300 in contact with the second semiconductor substrate 400 into the dielectric layer 300. In a direction normal to the first surface, a projection of the first trenches 410 overlaps with a projection of the plurality of chips 200, but a projection of the second trenches 310 does not overlap with the projection of the plurality of chips 200.

In the C2W structure and method provided in the present invention, the second semiconductor substrate 400 covering the plurality of chips 200 and the dielectric layer 300 provides heat dissipation properties several times better than the dielectric layer, allowing the resulting chip-to-wafer (C2W) heterogeneously integrated structure to have greatly improved heat dissipation performance.

As used herein, any reference to “one embodiment” or “some embodiments” means that a particular feature, structure, or characteristic described in connection with the embodiment is included in at least one embodiment or at least some embodiments disclosed herein. Therefore, the appearances of the phrase “in one embodiment” or “in some embodiments” in various places in the specification are not necessarily all referring to the same one or some embodiments. Further, in one or more embodiments, features, structures or characteristics may be combined in any suitable combination and/or sub-combination.

While some particular embodiments of the present application have been described in detail by way of examples, those skilled in the art will understand that the foregoing examples are provided for illustration only rather than any limitation on the scope of the application. The various embodiments disclosed herein can be combined in any combination, without departing from the spirit and scope of the application. Those skilled in the art will also understand that various modifications can be made to the embodiments, without departing from the scope and spirit of the application. The scope of the application is defined by the appended claims.

What is claimed is:

1. A chip-to-wafer (C2W) structure, comprising:
a first semiconductor substrate;
a plurality of chips located above the first semiconductor substrate;
a dielectric layer covering the first semiconductor substrate; and
a second semiconductor substrate covering the plurality of chips and the dielectric layer.

2. The C2W structure of claim 1, wherein at least one first trench is formed in the second semiconductor substrate, wherein the first trench extends from a first surface of the second semiconductor substrate that is in contact with the plurality of chips into the second semiconductor substrate.

3. The C2W structure of claim 2, wherein a plurality of first trenches are formed in the second semiconductor substrate, wherein the plurality of first trenches are arranged in a mesh structure along a first direction and a second direction.

4. The C2W structure of claim 2, wherein a plurality of first trenches are formed in the second semiconductor substrate, wherein the plurality of first trenches form a plurality of trench regions, and wherein each trench region is aligned with a corresponding chip.

5. The C2W structure claim 2, wherein a metal layer or a thermally conductive fluid is provided in the at least one first trench.

6. The C2W structure of claim 2, wherein the at least one first trench has a depth-to-width ratio lying between 1:1 and 2:1.

7. The C2W structure of claim 1, wherein a second trench is formed in the dielectric layer, wherein the second trench extends from a second surface of the dielectric layer that is in contact with the second semiconductor substrate into the dielectric layer.

8. The C2W structure of claim 7, wherein a single second trench surrounds at least one chip.

9. The C2W structure of claim 7, wherein a plurality of second trenches are formed in the dielectric layer, wherein each second trench surrounds a corresponding chip.

10. A method for making a chip-to-wafer (C2W) structure, comprising:
providing a first semiconductor substrate;
bonding a plurality of chips to the first semiconductor substrate;
covering the first semiconductor substrate with a dielectric layer; and
covering the plurality of chips and the dielectric layer with a second semiconductor substrate.

11. The method of claim 10, wherein covering the plurality of chips and the dielectric layer with the second semiconductor substrate comprises:
providing the second semiconductor substrate;
forming a first trench in the second semiconductor substrate, wherein the first trench extends from a first surface of the second semiconductor substrate into the second semiconductor substrate; and
covering the plurality of chips and the dielectric layer with the second semiconductor substrate, wherein the first surface comes into contact with the plurality of chips and the dielectric layer.

12. The method of claim 10, covering the first semiconductor substrate with the dielectric layer comprises:
forming the dielectric layer, wherein the dielectric layer covers surfaces of the chips and the first semiconductor substrate uncovered by the chip;
removing the dielectric layer above the surfaces of the chips; and
forming at least one second trench in the dielectric layer, wherein the at least second trench extends from a second surface of the dielectric layer into the dielectric layer.

13. The method of claim 11, wherein a metal layer or a thermally conductive fluid is provided in the first trench.

14. The method of claim 11, wherein the first trench has a depth-to-width ratio lying between 1:1 and 2:1.

15. The method of claim 12, wherein a single second trench surrounds at least one chip.
